(19) United States
(12) Patent Application Publication
(10) Pub. No.: US 2008/0131991 A1
(43) Pub. Date: Jun. 5, 2008

(54) METHOD OF MANUFACTURING CMOS IMAGE SENSOR

(76) Inventor: Sang-Sik Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/933,821

(22) Filed: Nov. 1, 2007

(30) Foreign Application Priority Data
Nov. 30, 2006 (KR) 10-2006-0119974

(51) Int. Cl. H01L 31/18

(52) U.S. Cl. 438/70; 257/E31.127

(57) ABSTRACT

A method of manufacturing a CMOS image sensor including a surface protection layer of an oxide-nitride-oxide (ONO) structure in order to minimize warping of the wafer by relieving thermal stresses of a silicon nitride layer, and to prevent blistering and popping by minimizing such thermal stresses.

The present application claims priority under 35 U.S.C. 119 to Korean Patent Application No. 10-2006-0119974 (filed on Nov. 30, 2006), which is hereby incorporated by reference in its entirety.

### BACKGROUND

A complementary metal oxide semiconductor (CMOS) image sensor may typically include a photo-sensing unit that receives light and a logic circuit unit that converts the light to electric signals.

In order to enhance photosensitivity the area occupied by the photo-sensing unit may be increased. However, since it is impossible to remove the logic circuit unit from the CMOS image sensor, a method for increasing the occupying area of the photo-sensing unit in the fixed entire area of the CMOS image sensor has limits.

Accordingly, light-condensing technology such as microlens processing, has been developed to condense light on the photo-sensing unit by changing the path of light incident on the remaining areas except the photo-sensing unit.

In order to receive color images, the image sensor may be provided with a color filter array formed on and/or over the photo-sensing unit, generates optical charges from the received light and accumulates the generated optical charges. The color filter array can include three color filters of red, green and blue. However, the color filter array may include yellow, magenta and cyan color filters.

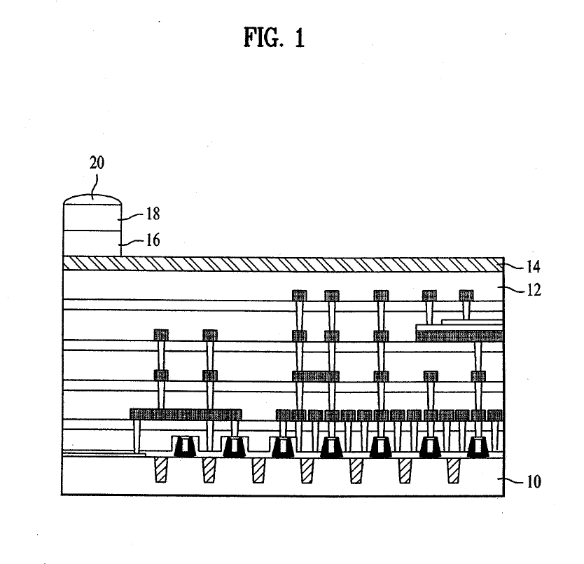

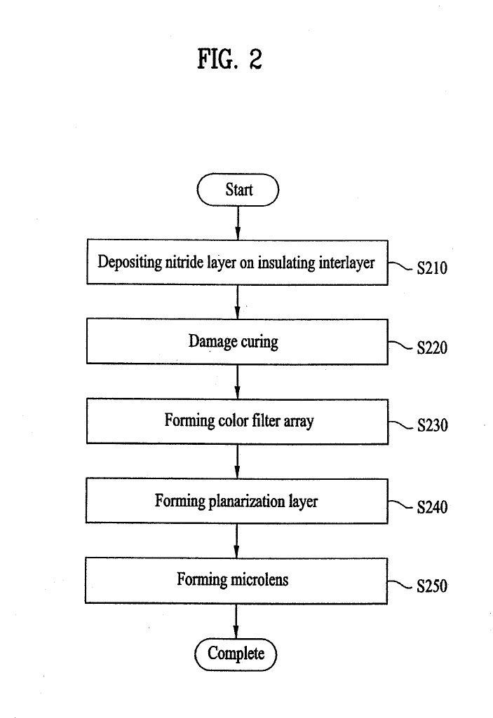

As illustrated in example FIGS. 1 and 2, a CMOS image sensor may include semiconductor substrate 10 including a pixel region and a transistor region; insulating interlayer 12 formed of un-doped silicon glass (USG) on and/or over semiconductor substrate 10. Silicon nitride layer 14 deposited on and/or over insulating interlayer 12 having a thickness between approximately 2900 Å and 3200 Å (S210). Then, a sintering process is applied to an entire surface of silicon nitride layer 14 whereby hydrogen (H) included in silicon nitride layer 14 may be diffused to the surface of semiconductor substrate 10 by out-diffusion, and may then be combined with a dangling bond, thereby realizing the damage-curing process which reduces the thickness of silicon nitride layer 14 (S220). Through the sintering process, the entire thickness of the silicon nitride layer 14 is decreased to 3000 Å.

Color filter array 16 can be arranged sequentially, can be formed on and/or over the pixel region of silicon nitride layer 14 (S230). Color filter array 16 can include red, green and blue color filters, or yellow, magenta and cyan color filters. Planarization layer 18 can then be formed on and/or over color filter array 16 (S240). Microlens 20 can be formed on and/or over planarization layer 18, thereby completing the CMOS image sensor (S250).

Such a method of manufacturing a CMOS image sensor, however, has the following disadvantages. Thermal stresses are applied differently applied to silicon nitride layer 14 and an oxide layer of insulating interlayer 12 including a lower layer of phosphorus silicate glass (PSG), un-doped silicate glass (USG) and fluorine-doped silicate glass (FSG). In a region upon which thermal stresses are concentrated, the stress is applied differently due to impurities in a tungsten (W) plug provided with a defective lower portion, the hygroscopic property of the oxide layer, and the density of the metal layer, thereby occurring blister or popping by Oug Gassing.

### SUMMARY

Embodiments relate to a method of manufacturing a CMOS image sensor including a surface protection layer of an oxide-nitride-oxide (ONO) structure.

Embodiments relate to a method of manufacturing a CMOS image sensor including at least one of the following steps: forming an insulating interlayer on and/or over a semiconductor substrate; sequentially depositing a silicon nitride layer and an oxide layer on and/or over the insulating interlayer; applying a sintering process to the entire surface of the semiconductor substrate including the silicon nitride layer and the oxide layer; removing the oxide layer by conducting an etching process; and sequentially forming a color filter array, a planarization layer and a microlens on and/or over the silicon nitride layer.

Embodiments relate to a method of manufacturing a CMOS image sensor including at least one of the following steps: providing a semiconductor substrate defined with pixel and transistor regions; forming an insulating interlayer over an entire surface of the semiconductor substrate; sequentially depositing a silicon nitride layer and an oxide layer over the insulating interlayer; relieving wafer stresses from the surface of the semiconductor substrate including the silicon nitride layer and the oxide layer; reducing thermal stresses of the silicon nitride layer caused by tensile stresses of the oxide layer, compressive stresses of the silicon nitride layer and tensile stresses of the insulating interlayer; removing the oxide layer using an etching process; and then sequentially forming a color filter array, a planarization layer and a microlens over the silicon nitride layer.

### DRAWINGS

Example FIG. 1 illustrates a CMOS image sensor.

Example FIG. 2 illustrates a flow chart of a method of manufacturing a CMOS image sensor.

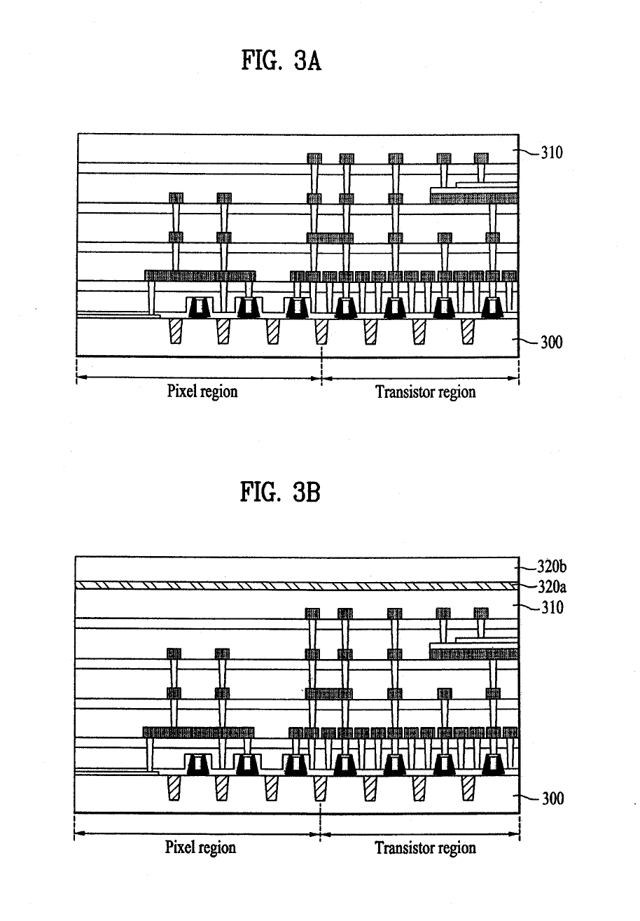

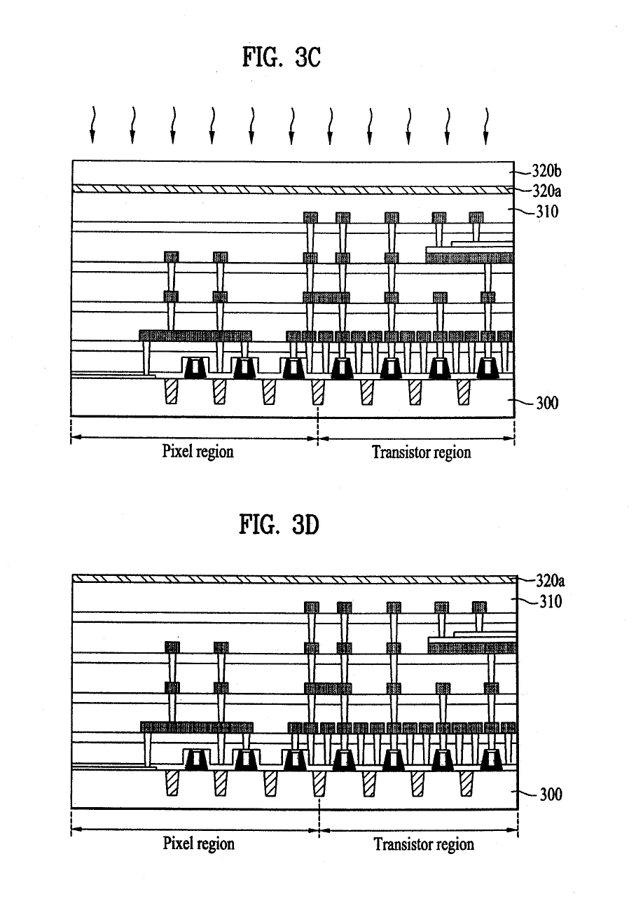

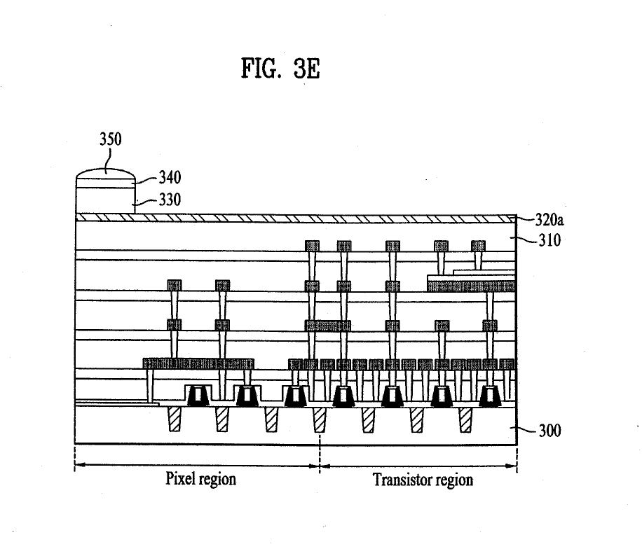

Example FIGS. 3A to 3E illustrate a method of manufacturing a CMOS image sensor, in accordance with embodiments.

### DESCRIPTION

As illustrated in example FIG. 3A, insulating interlayer 310 can be formed on and/or over an entire surface of semiconductor substrate 300 defined with pixel and transistor regions. Insulating interlayer 310 may be composed of un-doped silicate glass (USG).

As illustrated in example FIG. 3B, silicon nitride layer (SiN) 320a and oxide layer 320b can be sequentially deposited on and/or over insulating interlayer 310. Insulating interlayer 310 and oxide layer 320a may have substantially identical, i.e., the same, thicknesses. Oxide layer 320b may be composed of at least one of un-doped silicate glass (USG), phosphorus silicate glass (PSG) and ozone tetra ethyl silicate (O₃-TEOS).

To relieve a wafer stress from the entire surface of semiconductor substrate 300 including silicon nitride layer 320a and oxide layer 320b, additional steps may be performed in order to pattern using a photolithographic process scribe line and its peripheral region which require no silicon nitride layer 320a, and to isolate the patterned region by etching.

As illustrated in example FIG. 3C, a sintering process can be applied to the entire surface of semiconductor substrate 300 including silicon nitride layer 320a and oxide layer 320b. The sintering process can be performed for 10 to 60 minutes at a temperature range of between approximately 400° C. to 500° C.

Accordingly, thermal stresses caused by a tensile stress of oxide layer 320b, compressive stresses of silicon nitride layer 320a, and tensile stresses of insulating interlayer 310 may be reduced. In turn, blister and popping may be prevented.

As illustrated in example FIG. 3D, after completing the sintering process, oxide layer 320b can be removed using an etching process.

As illustrated in example FIG. 3E, color filter array 330, planarization layer 340 and microlens 350 can be sequentially formed on and/or over silicon nitride layer 320a, thereby completing the CMOS image sensor.

In order to provide color images, color filter array 330 can be positioned on and/or over a photo-sensing unit which receives external light, generates optical charges and accumulates the generated optical charges. Color filter array 330 may be formed of red, green and blue colors, or yellow, magenta and cyan colors.

In accordance with embodiments, the method of manufacturing the CMOS image sensor provides at least the following advantages. The surface protection layer having an ONO structure can be formed to minimize warping of the wafer by relieving the thermal stress of the silicon nitride layer, and may also prevent blistering and popping by minimizing the thermal stress.

What is claimed is:

1. A method comprising:
forming an insulating interlayer over a semiconductor substrate;
sequentially depositing a silicon nitride layer and an oxide layer over the insulating interlayer;
applying a sintering process to the entire surface of the semiconductor substrate including the silicon nitride layer and the oxide layer;
removing the oxide layer by etching; and
sequentially forming a color filter array, a planarization layer and a microlens over the silicon nitride layer.

2. The method of claim 1, wherein the oxide layer comprises un-doped silicate glass.

3. The method of claim 1, wherein the oxide layer comprises phosphorus-doped silicate glass.

4. The method of claim 1, wherein the oxide layer comprises ozone tetra ethyl silicate PSG.

5. The method of claim 1, wherein the sintering process is performed at a temperature between 400° C. and 500° C.

6. The method of claim 5, wherein the sintering process is performed for 10 to 60 minutes.

7. The method of claim 1, further comprising after sequentially depositing the silicon nitride layer and the oxide layer but before applying a sintering process to the entire surface of the semiconductor substrate:
patterning a scribe line and a peripheral region of the scribe line over the entire surface of the semiconductor substrate including the silicon nitride layer and the oxide layer; and then
isolating the patterned region.

8. The method of claim 7, wherein patterning a scribe line is performed using a photolithographic process.

9. The method of claim 8, wherein isolating the patterned region is performed using an etching process.

10. The method of claim 1, wherein the oxide layer is removed using an etching process.

11. A method comprising:
providing a semiconductor substrate defined with pixel and transistor regions;
forming an insulating interlayer over an entire surface of the semiconductor substrate;
sequentially depositing a silicon nitride layer and an oxide layer over the insulating interlayer;
relieving wafer stresses from the surface of the semiconductor substrate including the silicon nitride layer and the oxide layer;
reducing thermal stresses of the silicon nitride layer caused by tensile stresses of the oxide layer, compressive stresses of the silicon nitride layer and tensile stresses of the insulating interlayer;
removing the oxide layer using an etching process; and then
sequentially forming a color filter array, a planarization layer and a microlens over the silicon nitride layer.

12. The method of claim 11, wherein the insulating interlayer comprises un-doped silicate glass.

13. The method of claim 11, wherein sequentially depositing a silicon nitride layer and an oxide layer comprises depositing the insulating interlayer having a thickness substantially equal to the thickness of the oxide layer.

14. The method of claim 11, wherein the oxide layer comprises un-doped silicate glass.

15. The method of claim 11, wherein the oxide layer comprises phosphorus-doped silicate glass.

16. The method of claim 11, wherein the oxide layer comprises ozone tetra ethyl silicate PSG.

17. The method of claim 11, wherein reducing thermal stresses comprises performing a sintering process on the entire surface of the semiconductor substrate including the silicon nitride layer and the oxide layer.

18. The method of claim 17, wherein the sintering process is performed at a temperature between 400° C. and 500° C.

19. The method of claim 18, wherein the sintering process is performed for between 10 to 60 minutes.

20. The method of claim 11, wherein the color filter array is positioned over a photo-sensing unit.
